(19) United States
(12) Patent Application Publication
(10) Pub. No.: US 2014/0183547 A1
(43) Pub. Date: Jul. 3, 2014

(54) SEMICONDUCTOR DEVICE

(71) Applicant: Kabushiki Kaisha Toshiba, Minato-Ku (JP)

(72) Inventor: Kentaro IKEDA, Kanagawa-ken (JP)

(73) Assignee: Kabushiki Kaisha Toshiba, Minato-ku (JP)

(21) Appl. No.: 14/104,388

(22) Filed: Dec. 12, 2013

(30) Foreign Application Priority Data
Dec. 27, 2012 (JP) 2012-286241

(51) Int. Cl. H01L 27/06; H01L 29/20

(52) U.S. Cl. CPC H01L 27/0629; H01L 29/2003
USPC 257/76; 257/106

(57) ABSTRACT

According to an embodiment, a semiconductor device includes a base including a mounting portion having conductivity, and a terminal insulated from the mounting portion. The device also includes a semiconductor element provided on the mounting portion and having a first face and a second face opposite to the first face, the semiconductor element having an electrode electrically connected to the terminal on the first face, and contacting the mounting portion via the second face, and a resistance element electrically connecting the mounting portion to the terminal. A resistance value of the resistance element is greater than a reciprocal of the product ωC, wherein C is a capacitance value between the mounting portion and the terminal, and ω is an angular frequency of an electrical signal output from the semiconductor element.

### CROSS-REFERENCE TO RELATED APPLICATIONS

This application is based upon and claims the benefit of priority from Japanese Patent Application No. 2012-286241, filed on Dec. 27, 2012; the entire contents of which are incorporated herein by reference.

### FIELD

Embodiments are generally related to a semiconductor device.

### BACKGROUND

Many semiconductor devices include a semiconductor element in a package thereof. Thus, there is a risk for degrading the properties due to a parasitic capacitance, when the semiconductor element is housed in the package. Hence, there is a need to alleviate the effects of package-induced parasitic capacitance.

### BRIEF DESCRIPTION OF THE DRAWINGS

FIGS. 1A and 1B are schematic views illustrating a semiconductor device according to a first embodiment;

FIGS. 2A and 2B are schematic views illustrating a semiconductor device according to a first comparative example;

FIGS. 3A and 3B are schematic views illustrating a semiconductor device according to a second comparative example;

FIGS. 4A to 4C are schematic cross-sectional views illustrating semiconductor elements according to a variation of the first embodiment; and

FIGS. 5A and 5B are schematic views illustrating a semiconductor device according to a second embodiment.

### DETAILED DESCRIPTION

According to an embodiment, a semiconductor device includes a base including a mounting portion having conductivity, and a terminal insulated from the mounting portion. The device also includes a semiconductor element provided on the mounting portion and having a first face and a second face opposite to the first face, the semiconductor element having an electrode electrically connected to the terminal on the first face, and contacting the mounting portion via the second face, and a resistance element electrically connecting the mounting portion to the terminal. A resistance value of the resistance element is greater than a reciprocal of the product ωC, wherein C is a capacitance value between the mounting portion and the terminal, and ω is an angular frequency of an electrical signal output from the semiconductor element.

Embodiments are described hereinafter while referring to the drawings. Note that the drawings are schematic or simplified illustrations and relation ship between a thickness and a width of each part and proportions in size between parts may differ from actual parts. Also, even when identical parts are depicted, mutual dimensions and proportions may be illustrated differently depending on the drawing. Note that in the drawings and specification of this application, the same numerals are applied to constituents that have already appeared in the drawings and have been described, and repetitious detailed descriptions of such constituents are omitted.

### First Embodiment

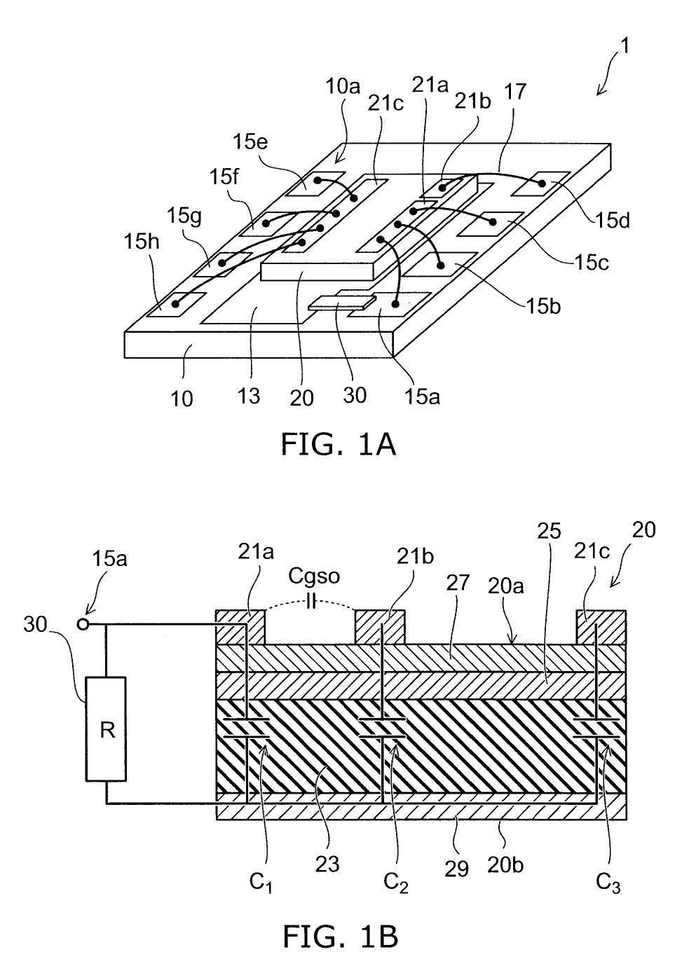

FIGS. 1A and 1B are schematic views illustrating a semiconductor device 1 according to a first embodiment. FIG. 1A is a perspective view illustrating a semiconductor element 20 mounted on a base 10. FIG. 1B is a cross-sectional view illustrating the semiconductor element 20.

The semiconductor device 1 is provided with the base 10 and the semiconductor element 20 mounted on the base 10. The base 10 includes a mounting portion 13 having conductivity, and a terminal 15 insulated from the mounting portion 13. The semiconductor element 20 is firmly mounted on the mounting portion 13. Further, the semiconductor element 20 has an electrode 21 electrically connected to the terminal 15 on a side opposite to a face that contacts the mounting portion 13. Furthermore, the mounting portion 13 and the terminal 15 are electrically connected via a resistance element 30.

As illustrated in FIG. 1A, the base 10 includes, for example, a plurality of terminals 15a to 15h mutually insulated. The terminals 15a to 15h are insulated from the mounting portion 13. For example, the base 10 is a ceramic substrate. The mounting portion 13 is a land pattern provided on a top surface 10a of the ceramic substrate, and the terminals 15a to 15h are bonding pads, for example. The land pattern and the bonding pads are, for example, metal films containing gold plated on a nickel layer. Alternatively, a resin substrate may be used for the base 10.

The semiconductor element 20 includes a plurality of electrodes 21. Each of the electrodes 21 is connected to the terminals 15 to 15h via metal wires, respectively. For example, the semiconductor element 20 is a field effect transistor (FET), and includes a source electrode 21a, a drain electrode 21c, and a gate electrode 21b. Here, the electrodes 21a to 21c that are bonding pads on the semiconductor element side are referred for convenience to as the same names as the source electrode 21a, the drain electrode 21c, and the gate electrode 21b to which they are respectively connected.

The source electrode 21a is connected to the terminals 15a, 15b, and 15c, respectively, via metal wires 17. The gate electrode 21b is connected to the terminal 15d via another metal wire 17. The drain electrode 21c is connected to the terminals 15e to 15h, respectively, via other metal wires 17.

Further, the resistance element 30 electrically connects the mounting portion 13 to one of the terminals 15a to 15h. In the embodiment, the resistance element 30 electrically connects the mounting portion 13 to the terminal 15a, and the terminal 15a is electrically connected to the source electrode 21a.

The mounting structure described above is one example, and the embodiment is not intended to be limited thereto. That is, any connection is possible between the semiconductor element 20 and the plurality of the terminals 15a to 15h, as long as an electrical connection is made via the resistance element 30 between the mounting portion 13 and one of the terminals desired to match the potential with the mounting portion 13.

As illustrated in FIG. 1B, the semiconductor element 20 has an electrode 21 on a first face 20a. The electrode 21 is electrically connected to the terminal 15a. Further, the resistance element 30 electrically connects the terminal 15a to a second face 20b on a side opposite the first face 20a.

More specifically, the semiconductor element 20 is, for example, an FET, and has the source electrode 21a, the gate electrode 21b and the drain electrode 21c on the first face 20a. Further, the source electrode 21a of the plurality of electrodes of the semiconductor element 20 is electrically connected to the terminal 15a. Meanwhile, the terminal 15a is electrically connected to the second face 20b of the semiconductor element 20 via the resistance element 30.

The semiconductor element 20 includes a channel layer 25 provided on a high-resistance substrate 23 and a barrier layer 27 provided on the channel layer 25. The high-resistance substrate 23 is, for example, a silicon carbide (SiC) substrate, a gallium nitride (GaN) substrate, or a sapphire substrate. Further, the channel layer 25 and the barrier layer 27 include a GaN semiconductor respectively. For example, the channel layer 25 is a GaN layer, and the barrier layer 27 is an AlGaN layer.

A back surface electrode 29, for example, is provided on the second face side of the high-resistance substrate 23. The back surface electrode 29 is, for example, a metal film. Further, the semiconductor element 20 is, for example, bonded to a mounting portion 13 via soldering material. Accordingly, the back surface electrode 29 is electrically connected to the mounting portion 13, and becomes the same potential as the mounting portion 13. That is, the terminal 15a is electrically connected to the back surface electrode 29.

The source electrode 21a and drain electrode 21c are in an ohmic contact with the barrier layer 27 and are electrically connected to the channel layer 25 via the barrier layer 27. Accordingly, a current can be supplied from the drain electrode 21c to the source electrode 21a via the channel layer 25. That is, the semiconductor element 20 is a horizontal FET that includes a current flow channel parallel to the first face 20a on which each of the electrodes is provided.

The gate electrode 21b is, for example, in Schottky contact with the barrier layer 27, so called the Schottky gate. Further, the current flowing through the channel layer 25 is controlled by a gate bias applied to the gate electrode 21b.

The semiconductor element 20 described above is one example, and the semiconductor element according to this embodiment is not intended to be limited to this. For example, the gate structure is not limited to the Schottky gate, and may be an insulated gate such as a metal oxide semiconductor (MOS) structure. Furthermore, the channel layer 25 is an active region of the semiconductor element 20 and includes, for example, a gallium nitride semiconductor.

The semiconductor device 2 may, for example, be housed in a hermetically sealed case, or may be sealed in resin. Further, the base 10 may be directly mounted on a circuit board. In other words, a package defined here is not just limited to ones sealing the semiconductor element 20 therein, but it also includes a form of a chip-on-carrier.

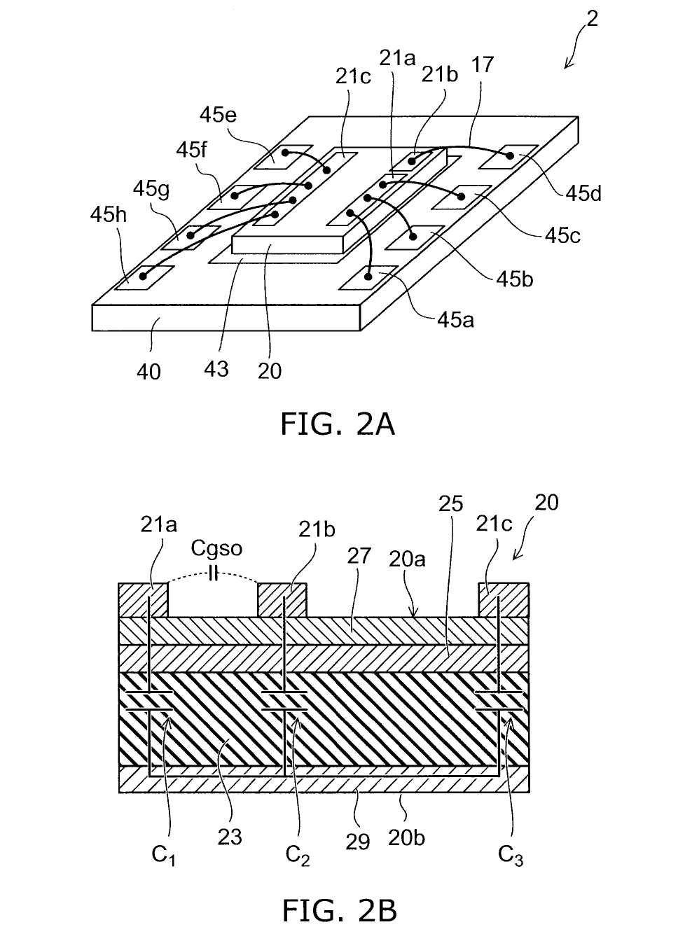

FIGS. 2A and 2B are schematic views illustrating a semiconductor device 2 according to a first comparative example. FIG. 2A is a perspective view illustrating the semiconductor element 20 mounted on a base 40. FIG. 2B is a cross-sectional view of the semiconductor element 20.

The semiconductor device 2 comprises the base 40 and the semiconductor element 20 mounted on the base 40. The base 40 includes a mounting portion 43 and a plurality of terminals 45a to 45h. The mounting portion 43 has conductivity, and the terminals 45a to 45h are electrically insulated from the mounting portion 43. The semiconductor element 20 is mounted on the mounting portion 43. The source electrode 21a, the gate electrode 21b, and the drain electrode 21c of the semiconductor element 20 are electrically connected to the terminals 45a to 45h via the metal wires 17, respectively.

FIG. 2B illustrates parasitic capacitances C₁, C₂, and C₃ induced by mounting the semiconductor element 20 on the base 40. For example, the package-induced parasitic capacitance C ₁ is added between the source electrode 21a and the back surface electrode 29 by mounting the semiconductor element 20 on the mounting portion 43 and electrically connecting the mounting portion 43 to the back surface electrode 29. Likewise, the parasitic capacitance C₂ is added between the gate electrode 21b and the back surface electrode 29, and the parasitic capacitance C₃ is added between the drain electrode 21c and the back surface electrode 29.

For example, when using the gallium nitride (GaN) FET provided on the conductive silicon substrate, an electrical distance between the back surface and each of the electrodes provided on the semiconductor surface substantially becomes narrower, and values for the parasitic capacitances C1 to C3 increase. Therefore, the effects of package-induced parasitic capacitance are further serious.

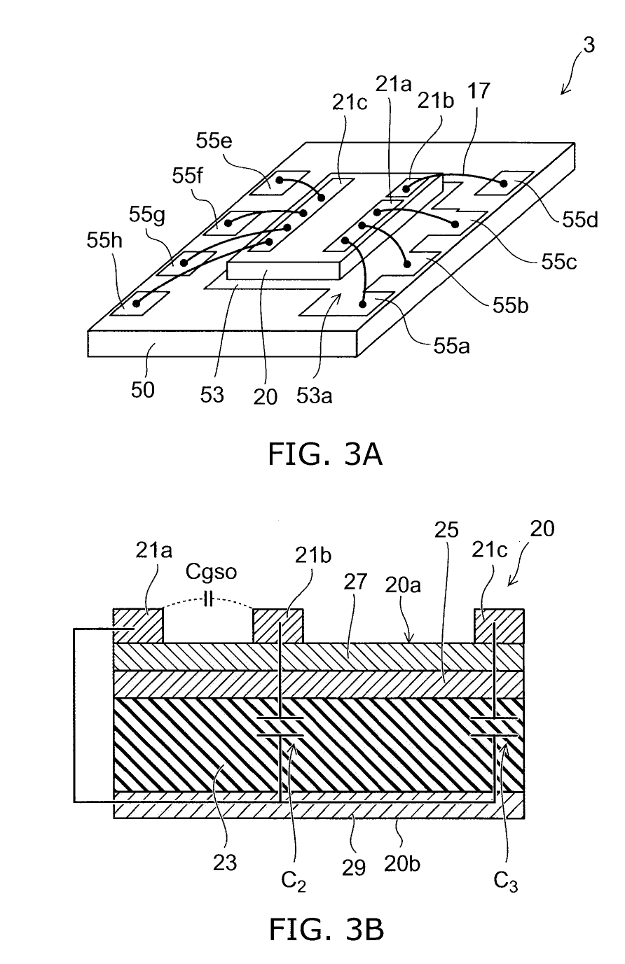

FIGS. 3A and 3B are schematic views illustrating a semiconductor device 3 according to a second comparative example. FIG. 3A is a perspective view illustrating the semiconductor element 20 mounted on a base 50. FIG. 3B is a cross-sectional view of the semiconductor element 20.

The semiconductor device 3 comprises the base 50 and the semiconductor element 20 mounted on the base 50. The base 50 includes a mounting portion 53 having conductivity, and terminals 55a to 55h. The terminals 55a to 55c are electrically connected to the mounting portion 53 via a connecting portion 53a, and the terminals 55d to 55h are insulated from the mounting portion 53. The source electrode 21a, the gate electrode 21b, and the drain electrode 21c of the semiconductor element 20 are electrically connected to the terminals 55a to 55h via the metal wires 17, respectively.

FIG. 3B illustrates the parasitic capacitances C₂ and C₃ induced by mounting the semiconductor element 20 on the base 50. In this case, the terminals 55a to 55c are connected to the mounting portion 53 and become the same potential as the back surface electrode 29, and therefore, the parasitic capacitance C₁ is not induced. Meanwhile, in the gate electrode 21b and the drain electrode 21c connected to a terminal electrically insulated from the mounting portion 53, the parasitic capacitance C₂ is induced between the gate electrode 21b and the back surface electrode 29, and the parasitic capacitance C₃ is induced between the drain electrode 21c and the back surface electrode 29.

In the semiconductor device 2 illustrated in FIG. 2B, C₁ is induced between the source electrode 21a and the back surface electrode 29 of the semiconductor element 20, and C₂ is induced between the gate electrode 21b and the back surface electrode 29, respectively. Therefore, series capacitors of C₁ and C₂ are provided between the gate and the source of the semiconductor element 20.

When a gate to source capacitance in a chip state of the semiconductor element 20 is C_{gs0}, a gate to source capacitance C_{gs2} after being mounted on the base 50 is expressed in the following equation.

C_{gs2}=C_{gs0}+C₁×C₂/(C₁+C₂) (1)

Meanwhile, C₁ is not induced in the semiconductor device 3, and therefore, a gate to source capacitance C_{gs3} after being mounted on the base 40 is

C_{gs3}=C_{gs0}30 C₂ (2).

### Since

C₁33 C₂/(C₁+C₂)<C₂ (3),

C_{gs2} is less than C_{gs3}. This is not limited to the gate to source capacitance, but a similar relationship also occurs in a drain to source capacitance.

Meanwhile, series capacitors C₂ and C₃ are provided between the gate and the drain regardless of whether there is a connection between the terminal and the mounting portion or not. Therefore, an influence of the parasitic capacitance between the gate and the drain is less than that between the gate and the source or that between the drain and the source.

In this manner, in the semiconductor device 2 using the base 40 in which all terminals 45a to 45h are insulated from the mounting portion 43, the influence of the package-induced parasitic capacitance is reduced more than the semiconductor device 3 using the base 50 in which a portion of the terminals and the mounting portion 53 are connected and have the same potential.

However, in the semiconductor device 2, the potential of the mounting portion 43 is a floating potential. Therefore, the operation of the semiconductor element 20 is unstable, and may lead to element breakage when a large amplitude voltage is applied. Further, the mounting portion 43 may be kept in a higher voltage state, in which electric charges have been accumulated due to a leakage of the semiconductor element 20. Accordingly, there may be a risk of generating a negative effect on the reliability of the semiconductor device 2 owing to the potential of the mounting portion 43 not fixed.

Conversely, in the embodiment, the terminal 15a and the mounting portion 13 are electrically connected via the resistance element 30 as illustrated in FIG. 1A. Accordingly, the potential of the mounting portion 13 is stably held for the terminal 15a.

Further, the resistance element 30 is connected in parallel to the parasitic capacitance C₁ between the source electrode 21a and the back surface electrode 29 as illustrated in FIG. 1B. The gate to source capacitance C_{gs1} of the semiconductor device 1 becomes effectively closer to the gate to source capacitance C_{gs2} of the semiconductor device 2 as a resistance value R of the resistance element 30 increases. Meanwhile, the gate to source capacitance C_{gs1} substantially becomes closer to the gate to source capacitance C_{gs3} of the semiconductor device 3 as the resistance value R of the resistance element 30 approaches zero. That is to say, an effective value of the gate to source capacitance C_{gs1} is an intermediate value between C_{gs2} and C_{gs3}.

Accordingly, the semiconductor element 20 according to this embodiment can mitigate the influence of parasitic capacitances C₁ and C₂ by providing the resistance element 30. This advantage is not limited to the gate to source capacitance C_{gs1}, but this advantage can be obtained in the same way for a drain to source capacitance C_{ds1}.

The resistance value of the resistance element 30 is preferably, for example, greater than an absolute value |1/ωC₁| of the reactance resulting from the parasitic capacitance C₁. This allows reducing the influence of the parasitic capacitance C₂ effectively. Note that, co (radian/second) is an angular frequency of the electrical signal output from the semiconductor element 20 and is expressed by the following equation (4). The parasitic capacitance C₁ is also a capacitance value between the terminal 15a and the mounting portion 13.

ω=2nf (4)

For example, when an electric signal is a sine wave, f is the frequency thereof (Hz). Further, when the electrical signal has a pulse waveform, the pulse rise time or pulse fall time of the output waveform is treated as t (second), and an approximation of f=0.35/t is used.

In this manner, in the embodiment, the influence of the parasitic capacitance generated by mounting the semiconductor element 20 on the package is reduced, and furthermore, the stabilization of the potential is achieved in the mounting portion on which the semiconductor element 20 is mounted. Thereby, it becomes possible to improve the properties of the semiconductor element 20.

For example, it may be possible to improve switching speed thereof by reducing the influence of the gate to source capacitance C_{gs1} and the drain to source capacitance C_{ds1} of the semiconductor element 20. Further, in a semiconductor element having a field plate (FP) electrode, FP effect can be effectively maintained by stabilizing the potential of the mounting portion 13.

For example, in the case of a GaN FET provided on a silicon substrate, the embodiment may effectively mitigate the influence of parasitic capacitances C1 to C3. Further, by maintaining the FP effect, an element breakdown voltage can be effectively improved, and it may also suppress the resistance increase or decrease referred to as so-called collapse. That is to say, a synergetic effect can be obtained in the GaN FET provided on the silicon substrate by reducing the parasitic capacitance and improving the properties due to the field plate.

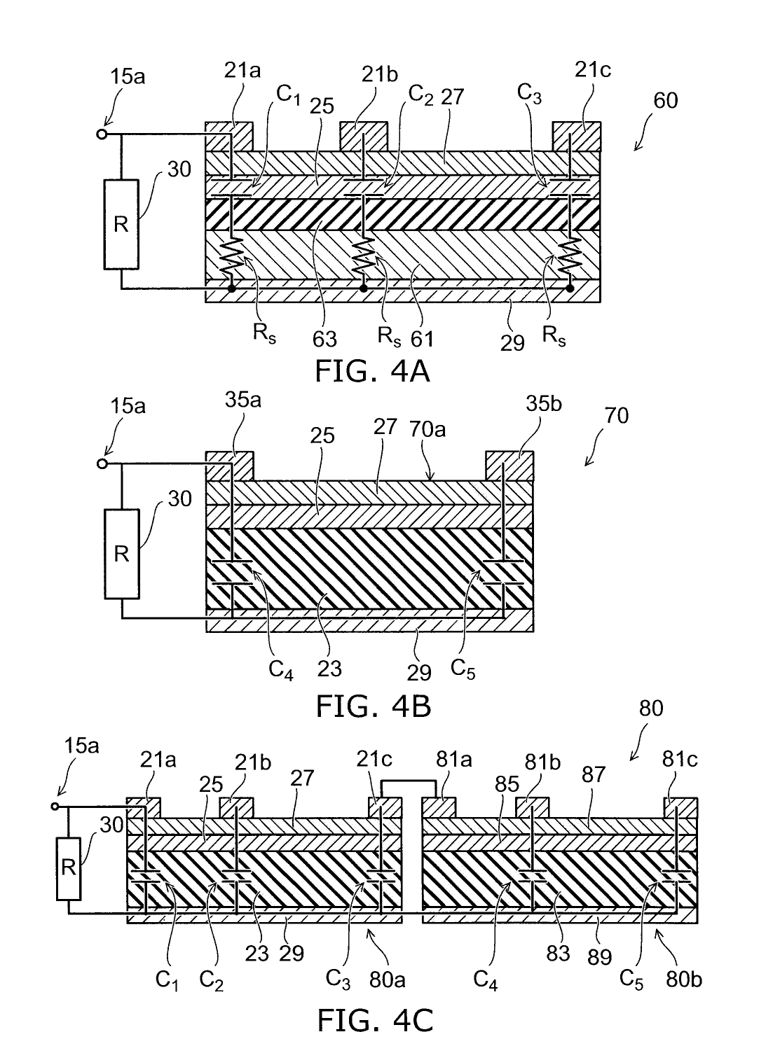

FIGS. 4A to 4C are schematic cross-sectional views illustrating semiconductor elements according to a variation of the first embodiment. Constituents are mounted on the base 10 as illustrated in FIG. 1A, respectively. Note that, when referencing “terminal 15” in the following description, it indicates any of the terminals 15b to 15h.

A semiconductor element 60 illustrated in FIG. 4A includes a conductive substrate 61 and a high-resistance layer 63 provided thereon. The conductive substrate 60 is, for example, a silicon substrate. The high-resistance layer 63 is a buffer layer provided between the conductive substrate and the channel layer 25. Alternatively, the semiconductor element 60 may be a silicon FET using silicon on insulator (SOI) substrate.

In the semiconductor element 60 having a substrate with conductivity, a position of the back surface electrode 29 shifts substantially to the back surface of the high-resistance layer 63. Accordingly, the values of the parasitic capacitances C1 to C3 become greater than in the case where the insulating substrate is used, as described above. Therefore, reducing the influence of the parasitic capacitances C1 to C3 by the embodiment is more advantageous.

A substrate resistance R_{S} is added in series to the parasitic capacitances C₁, C₂, and C₃, respectively, in the semiconductor element 60. Further, the substrate resistance R_{S} is connected in series to the resistance element 30. Therefore, the similar advantage is achieved as when increasing the resistance value R of the resistance element 30. That is to say, the influence of the parasitic capacitances C₁, C₂, and C₃ can be reduced, and the influence of the gate to source capacitance C_{gs1} and the drain to source capacitance C_{ds1} can also be reduced.

A semiconductor element 70 illustrated in FIG. 4B is a Schottky diode having an anode 35a and a cathode 35b on a first face 70a. For example, a Schottky junction is provided between the anode 35a and the barrier layer 27, and an ohmic junction is provided between the cathode 35b and the barrier 27.

The node 35a is connected to, for example, the terminal 15a via the metal wire 17. Therefore, a parasitic capacitance C₄ is added between the anode 35a and the back surface electrode 29. The cathode 35b s also connected to the terminal 15 via the metal wire 17, and a parasitic capacitance C₅ is added between the cathode 35b and the back surface electrode 29. According to the embodiment, the influence of the parasitic capacitances C ₄ and C₅ can be reduced, and the influence of the anode to cathode capacitance can be reduced by electrically connecting between the terminal 15a and the back surface electrode 29 via the resistance element 30.

In a semiconductor element 80 illustrated in FIG. 4C, two FETs 80a and 80b are connected in series. The FETs 80a and 80b are firmly mounted on one mounting portion 13. Accordingly, the back surface electrode 29 of the FET 80a is electrically connected to a back surface electrode 89 of the FET 80b and both become the same potential. Further, the drain electrode 21c of the FET 80a and a source electrode 81a of the FET 80b are, for example, electrically connected via a metal wire.

The source electrode 21a of the FET 80a is electrically connected to the terminal 15a via the metal wire 17. The terminal 15a and the mounting portion 13 are electrically connected via the resistance element 30. Thereby, the influence of the gate to source capacitance and the drain to source capacitance of the FET 80a can be reduced.

In this example, the drain electrode 21c and the terminal 15 of the FET 80a are electrically connected via the metal wire 17. Accordingly, the parasitic capacitance C₃ of the terminal 15 is added between the drain electrode 21c and the back surface electrode 29. Then, the influence of the parasitic capacitance C₃ is also reduced by the resistance element 30, and the influence of the drain to source capacitance is reduced. Series capacitors of the parasitic capacitances C₂ and C₃ are added between the gate and the drain; however, influences thereof are less than the parasitic capacitance added between the gate and the source as well as the parasitic capacitance added between the drain and the source.

In the FET 80b, the parasitic capacitance C₄ is induced between a gate electrode 81b and the back surface electrode 89, and the parasitic capacitance C₅ is induced between a gate electrode 81c and the back surface electrode 89. Further, series capacitors of C₃ and C₄ are added between the gate and the source of the FET 80b, and series capacitors of C₃ and C₅ are added between the drain and the source. Furthermore, series capacitors of C₄ and C₅ are added between the gate and the drain. These are all caused by the parasitic capacitance of the terminal 15 insulated from the mounting portion 13, and therefore, the effect of the parasitic capacitance for the FET 80b is less than that for the FET 80.

Accordingly, in the semiconductor element 80, the gate to source capacitance and the drain to source capacitance of the FET 80a can be reduced by electrically connecting between the terminal 15a and the mounting portion 13 via the resistance element 30. Thereby, the properties of the semiconductor element 80 can be improved. As described above, when the FETs connected in series are housed in a package, the parasitic capacitance is increased as the number of the FETs increases; however, it can be possible to reduce the influence thereof according to the embodiment.

In the example described above, each of the FET 80a and FET 80b is a separate chip; however, a semiconductor element in which two FETs are monolithically integrated may be used. Further, three or more FETs may be connected in series.

### Second Embodiment

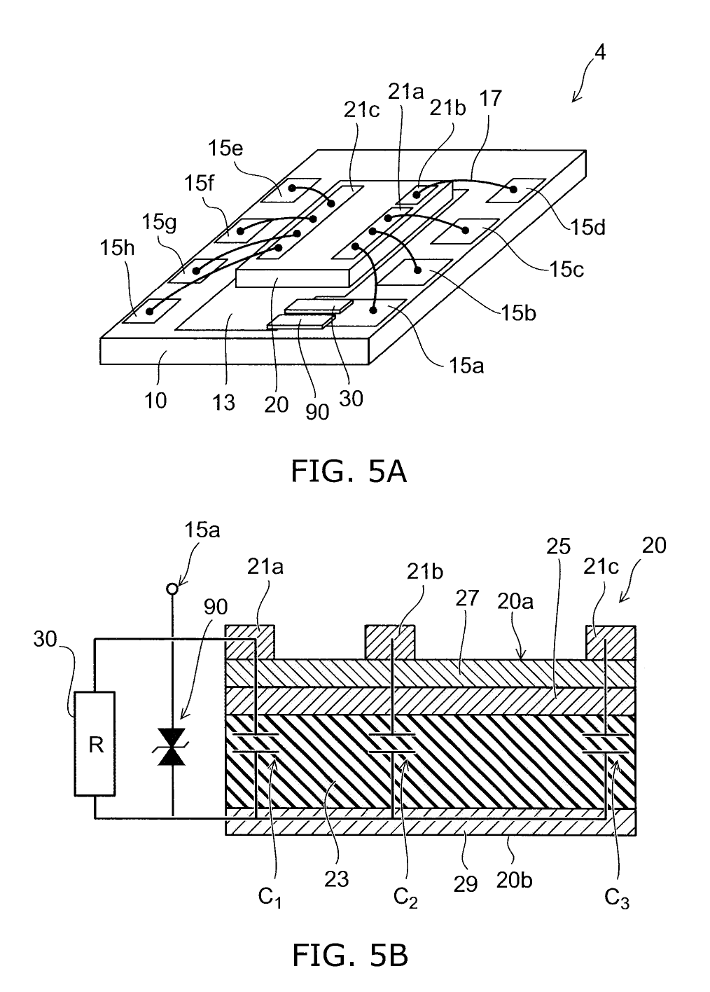

FIGS. 5A and 5B are schematic views illustrating a semiconductor device 4 according to a second embodiment. FIG. 5A is a perspective view illustrating the semiconductor element 20 mounted on the base 10. FIG. 5B is a cross-sectional view illustrating the semiconductor element 20.

The semiconductor device 4 is provided with the base 10 and the semiconductor element 20 mounted on the base 10. The semiconductor element 20 includes the source electrode 21a, the drain electrode 21c, and the gate electrode 21b, and all are connected to the terminals 15a to 15h of the base 10 via the metal wires 17, respectively. The source electrode 21a is connected to the terminals 15a, 15b, and 15c. The gate electrode 21b is connected to the terminal 15d. The drain electrode 21c is connected to the terminals 15e to 15h.

In the embodiment, a bidirectional diode 90 is provided in parallel with the resistance element 30 between the terminal 15a and the mounting portion 13. That is, a first terminal of the bidirectional diode 90 is connected to the terminal 15a and a second terminal is connected to the mounting portion 13.

In other words, as illustrated in FIG. 5B, the bidirectional diode 90 is provided in parallel with the resistance element 30 between the terminal 15a and the second face 20b of the semiconductor element 20. That is, the bidirectional diode 90 electrically connects between the terminal 15 and the back surface electrode 29.

The bidirectional diode 90 is, for example, a bidirectional Zener diode, and can be set to any breakdown voltage. For example, the bidirectional Zener diode having a breakdown voltage of 5V is used. This allows the potential of the mounting portion 13 to be suppressed within a range of ±5V, and the semiconductor element 20 to be operated stably. Further, breakdown of the semiconductor element 20 due to the application of a high voltage can be prevented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a base including a mounting portion having conductivity, and a terminal insulated from the mounting portion;
a semiconductor element provided on the mounting portion, and having a first face and a second face opposite to the first face, the semiconductor element having an electrode electrically connected to the terminal on the first face, and contacting the mounting portion via the second face; and
a resistance element electrically connecting the mounting portion to the terminal,
a resistance value of the resistance element being greater than a reciprocal of the product ωC, wherein C is a capacitance value between the mounting portion and the terminal, and ω is an angular frequency of an electrical signal output from the semiconductor element.

2. The device according to claim 1, further comprising a bidirectional diode provided in parallel with the resistance element between the mounting portion and the terminal.

3. The device according to claim 2, wherein the bidirectional diode is a bidirectional Zener diode.

4. The device according to claim 1, wherein the semiconductor element is a transistor having a plurality of the electrodes, and
the terminal is connected to a source electrode of the electrodes.

5. The device according to claim 1, wherein the semiconductor element has a current flow channel parallel to the first face.

6. The device according to claim 1, wherein the semiconductor element includes a high-resistance substrate, a channel layer provided on the high-resistance substrate, and a barrier layer provided on the channel layer.

7. The device according to claim 6, wherein the channel layer and the barrier layer include a gallium nitride semiconductor.

8. The device according to claim 1, wherein the semiconductor element includes a silicon substrate, a high-resistance layer provided on the silicon substrate, and the channel layer provided on the high-resistance layer.

9. The device according to claim 8, wherein the channel layer includes a gallium nitride semiconductor.

10. The device according to claim 1, wherein the semiconductor element includes a plurality of field effect transistors connected in series.

11. The device according to claim 1, wherein the terminal has a same potential as the mounting portion.

12. The device according to claim 1, wherein the semiconductor element is a Schottky diode having an anode and a cathode on the first face, and the cathode is electrically connected to the terminal.

13. The device according to claim 1, wherein the base is either a ceramic substrate or a resin substrate.

14. A semiconductor device, comprising:
a semiconductor element having an electrode on a first face, and a current flow channel parallel to the first face;
a terminal electrically connected to the electrode; and
a resistance element electrically connecting the terminal to a second face on a side opposite the first face.

15. The device according to claim 14, further comprising a bidirectional diode provided in parallel with the resistance element between the second face and the terminal.

16. The device according to claim 14, wherein a resistance value of the resistance element is greater than a reciprocal of the product ωC, wherein C is a capacitance value between the terminal and the second face, and w is an angular frequency of an electrical signal output from the semiconductor element.

17. The device according to claim 14, wherein the semiconductor element is a transistor having a plurality of the electrodes, and
the terminal is connected to a source electrode of the electrodes.

18. The device according to claim 14, wherein the terminal has a same potential as the second face.

19. The device according to claim 14, wherein the semiconductor element includes a high-resistance substrate, a channel layer provided on the high-resistance substrate, and a barrier layer provided on the channel layer.

20. The device according to claim 14, wherein the semiconductor element includes a silicon substrate, a high-resistance layer provided on the silicon substrate, and the channel layer provided on the high-resistance layer.
